(19) United States
(12) Patent Application Publication
(10) Pub. No.: US 2026/0068486 A1
(43) Pub. Date: Mar. 5, 2026

(54) Display Device and Manufacture Method Thereof

(71) Applicant: LG Display Co., Ltd., Seoul (KR)

(72) Inventors: SangHoon Jeong, Paju-si (KR); NamKil Park, Paju-si (KR)

(21) Appl. No.: 19/255,026

(22) Filed: Jun. 30, 2025

(30) Foreign Application Priority Data
Sep. 4, 2024 (KR) 10-2024-0120033

(51) Int. Cl. H10K 59/80; H10K 59/12; H10K 102/00

(52) U.S. Cl. CPC H10K 59/8722; H10K 59/1201; H10K 59/8793; H10K 2102/311

(57) ABSTRACT

Disclosed is a display device and manufacture method thereof. The display device includes a cover window; a display panel below the cover window, including an active area, a first non-active area surrounding the active area, a bending area extending from one side of the first non-active area to be bent, and a second non-active area extending from one side of the bending area; a frame below the display panel; adhesive layers between the display panel and the cover window and between the display panel and the frame; a molding member below the cover window and covering a side surface of the display panel, side surfaces of the adhesive layers, a side surface of the frame, and a part of a bottom surface of the frame, and a side surface of some of the adhesive layers has an inwardly concave shape in a part of the interface with the molding member.

### CROSS-REFERENCE TO RELATED APPLICATION

This application claims the priority and benefit of Republic of Korea Patent Application No. 10-2024-0120033 filed on Sep. 4, 2024, which is hereby incorporated by reference in its entirety.

### BACKGROUND

### Field

The present disclosure relates to a display device, and more particularly, for example, without limitation, to a display device and a manufacture method of a display device with an improved bonding strength between components of the display device.

### Description of the Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, an organic light emitting display device is a self-emitting display device so that a separate light source is not necessary, which is different from the liquid crystal display device. Therefore, the organic light emitting display device may be manufactured to have a light weight and a small thickness. Further, since the organic light emitting display device is driven at a low voltage so that it is advantageous not only in terms of power consumption, but also in terms of color implementation, a response speed, a viewing angle, and a contrast ratio (CR). Therefore, it is expected to be utilized in various fields.

### SUMMARY

The inventor has realized that in the related art, there is limitation on a size and life of display device. Accordingly, an object to be achieved by the present disclosure is to provide a display device which minimizes or at least reduces a size of a bezel area.

Another object to be achieved by the present disclosure is to provide a display device which relieves a stress due to contraction and expansion of a display panel and a molding member.

Objects of the present disclosure are not limited to the above-mentioned objects, and other objects, which are not mentioned above, can be clearly understood by those skilled in the art from the following descriptions.

According to an embodiment of the present disclosure, a display device includes a cover window; a display panel below the cover window, including an active area, a first non-active area surrounding the active area, a bending area extending from one side of the first non-active area to be bent, and a second non-active area extending from one side of the bending area; a frame below the display panel; a plurality of adhesive layers between the display panel and the cover window and between the display panel and the frame; a molding member below the cover window so as to cover a side surface of the display panel, side surfaces of the plurality of adhesive layers, a side surface of the frame, and a part of a bottom surface of the frame, and a side surface of some of the plurality of adhesive layers has an inwardly concave shape in a part of the interface with the molding member.

According to another aspect of the present disclosure, provided is a manufacture method of a display device, comprising: forming a display panel including an active area, a non-active area adjacent to the active area, and a bending area extending from one side of the non-active area; forming a cover window over the display panel; forming a frame below the display panel; forming a plurality of adhesive layers between the display panel and the cover window and between the display panel and the frame; and forming a molding member below the cover window so as to cover a side surface of the display panel, side surfaces of the plurality of adhesive layers, a side surface of the frame, and a part of a bottom surface of the frame, wherein a side surface of some of the plurality of adhesive layers has an inwardly concave shape in a part of an interface with the molding member.

According to another embodiment of the present disclosure, provided is a manufacture method of a display device, comprising: forming a display panel including an active area, a non-active area adjacent to the active area, and a bending area extending from one side of the non-active area; forming a cover window over the display panel; forming a molding member below the cover window so as to cover a side surface of the display pane; forming an adhesive layer on the top and the bottom of the display panel so that a side surface of the adhesive layer is covered by the molding member, wherein an interface of the molding member and the adhesive layer has a shape protruding toward the adhesive layer.

Other detailed matters of the exemplary embodiments are included in the detailed description and the drawings.

According to the present disclosure, a space required to protect an outside of the display panel is minimized or at least reduced to implement a narrow bezel.

According to the present disclosure, a stress generated between the display panel and the molding member is relieved to improve the durability of the display device.

According to the present disclosure, the stress of the display panel is reduced to improve the lifespan of the display device to be driven at a low power.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1A is a plan view of a display device according to an exemplary embodiment of the present disclosure before being bent;

FIG. 1B is a rear view of a display device according to an exemplary embodiment of the present disclosure after being bent;

FIG. 2 is a cross-sectional view taken along A-A′ of FIG. 1A according to an exemplary embodiment of the present disclosure;

FIG. 3 is a cross-sectional view taken along B-B′ of FIG. 1B according to an exemplary embodiment of the present disclosure;

FIG. 4 is a cross-sectional view taken along C-C′ of FIG. 1B according to an exemplary embodiment of the present disclosure;

FIGS. 5A and 5B are enlarged cross-sectional views of an area D of FIG. 4 according to an exemplary embodiment of the present disclosure;

FIG. 6 is a cross-sectional view of a display device according to another exemplary embodiment of the present disclosure;

FIG. 7A is an enlarged cross-sectional view of an area E of FIG. 6 according to an exemplary embodiment of the present disclosure;

FIG. 7B is an enlarged cross-sectional view of an area F of FIG. 6 according to an exemplary embodiment of the present disclosure;

FIG. 8 is a cross-sectional view of a display device according to still another exemplary embodiment of the present disclosure;

FIG. 9A is an enlarged cross-sectional view of an area E of FIG. 8 according to an exemplary embodiment of the present disclosure; and

FIG. 9B is an enlarged cross-sectional view of an area F of FIG. 8 according to an exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and characteristics of the present disclosure and a method of achieving the advantages and characteristics will be clear by referring to exemplary embodiments described below in detail together with the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers of elements and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “include,” “have,” “comprise,” “contain,” “constitute,” “make up of,” “formed of,” and “consist of” used herein are generally intended to allow other components to be added unless the terms are used with the term “only”. Any references to singular may include plural unless expressly stated otherwise.

A dimension including a size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Components are interpreted to include an ordinary error range even if not expressly stated.

When the position relation between two parts is described using the terms such as “on”, “above”, “over”, “below”, “under”, “beside”, “beneath”, “near”, “close to,” “adjacent to”, “on a side of”, “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the embodiments of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, the present disclosure will be described in detail with reference to accompanying drawings.

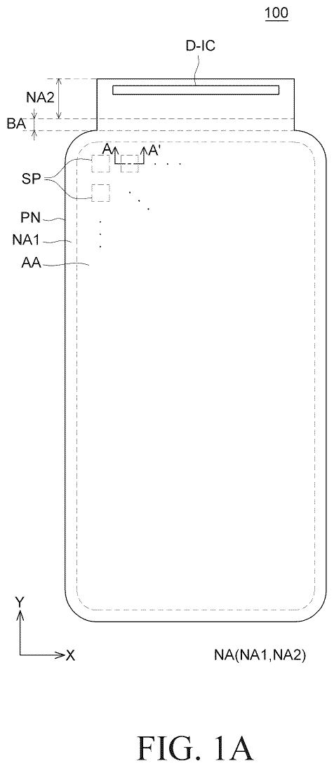

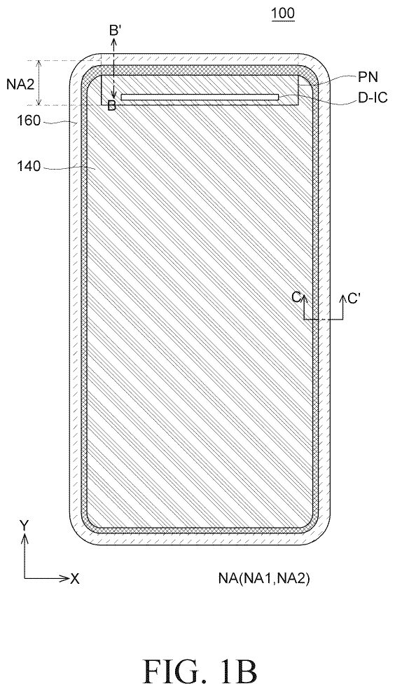

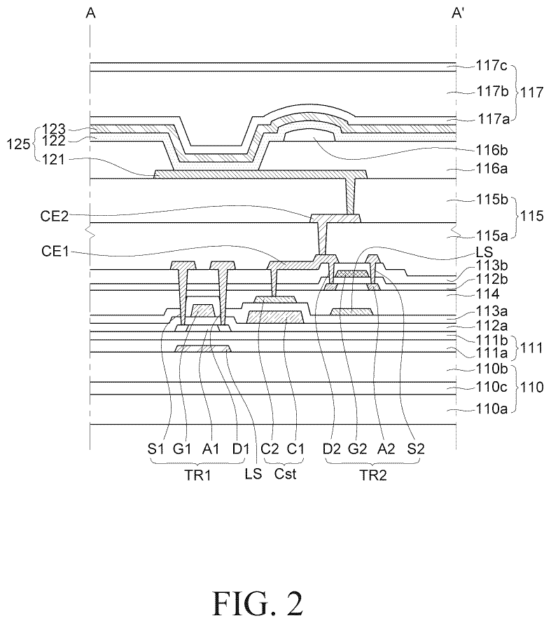

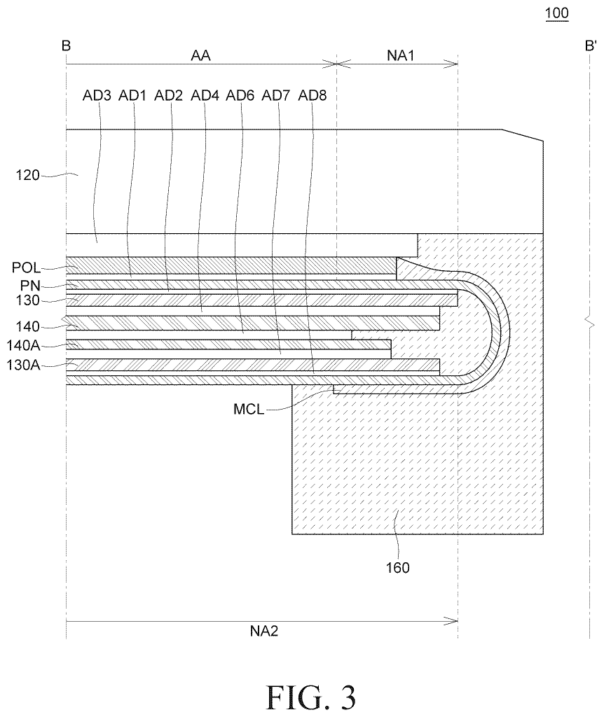

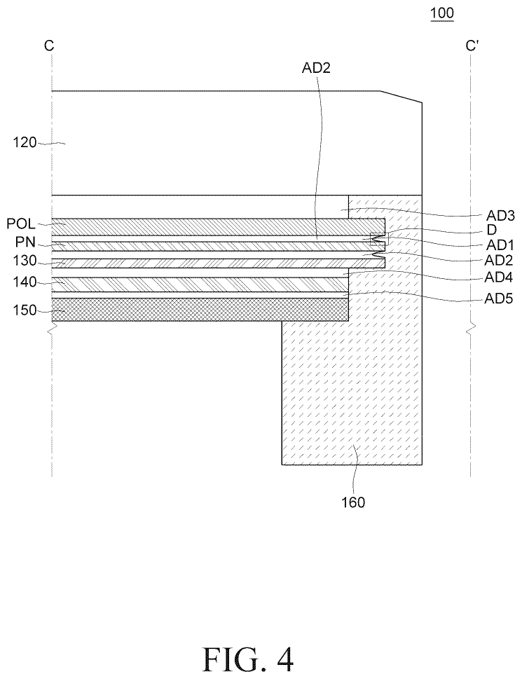

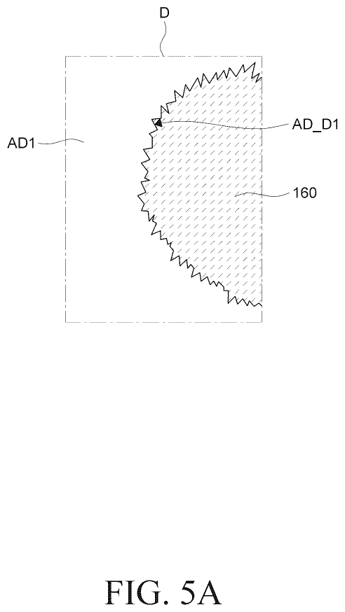

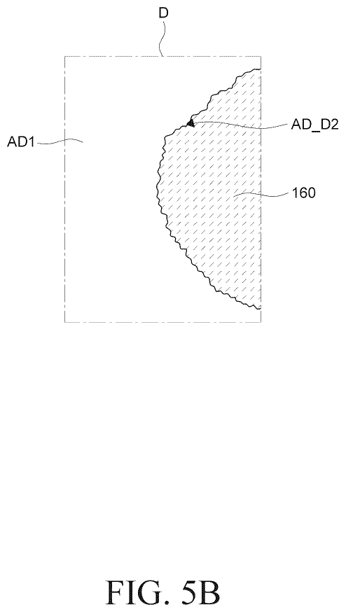

FIG. 1A is a plan view of a display device according to an exemplary embodiment of the present disclosure before being bent. FIG. 1B is a rear view of a display device according to an exemplary embodiment of the present disclosure after being bent. FIG. 2 is a cross-sectional view taken along A-A′ of FIG. 1A according to an exemplary embodiment of the present disclosure. FIG. 3 is a cross-sectional view taken along B-B′ of FIG. 1B according to an exemplary embodiment of the present disclosure. FIG. 4 is a cross-sectional view taken along C-C′ of FIG. 1B according to an exemplary embodiment of the present disclosure. FIG. 5A is an enlarged view of an area D of FIG. 4 according to an exemplary embodiment of the present disclosure. FIG. 5B is an enlarged cross-sectional view of an area D of FIG. 4 according to an exemplary embodiment of the present disclosure. FIG. 2 is a cross-sectional view for one sub pixel among a plurality of sub pixels of a display device. In FIGS. 1A to 5B, for the convenience of description, among components of a display device 100, only a display panel PN, a cover window 120, a back plate 130, a metal plate 140, a frame 150, and a molding member 160 are illustrated. In FIG. 1A, for the convenience of illustration, the hatching of the display panel PN is omitted.

In FIGS. 1A to 4, a display device 100 according to the present disclosure further includes a display panel PN, a cover window 120, a back plate 130, a metal plate 140, a frame 150, a molding member 160, and a plurality of adhesive layers AD1, AD2, AD3, AD4, AD5, AD6, AD7, and AD8.

The display panel PN is a panel for displaying images to a user. In the display panel PN, a display element which displays images, a driving element which drives the display element, and wiring lines which transmit various signals to the display element and the driving element are disposed.

The display element may be defined in different manners depending on the type of the display panel PN. For example, when the display panel PN is an organic light emitting display panel PN, the display element may be an organic light emitting diode which includes an anode, an organic emission layer, and a cathode. For example, when the display panel PN is a liquid crystal display panel, the display element may be a liquid crystal display element. Hereinafter, even though the display panel PN is assumed as an organic light emitting display panel, the display panel PN is not limited to the organic light emitting display panel.

The display panel PN includes an active area AA and a non-active area NA. For example, the display panel PN may include an active area AA including a plurality of pixels and a non-active area NA fully or partially surrounding the active area AA. The flat surface shape of the active area AA may have a rectangular shape. However, the exemplary embodiments of the present disclosure are not limited thereto, and the flat surface shape of the active area AA may be a square, circular, elliptical, or other polygonal shapes. For example, the active area AA may have a rectangular shape with rounded corners, but is not limited thereto and may also have a rectangular shape with angled corners.

The active area AA is an area where images are displayed in the display panel PN. In the active area AA, a plurality of sub pixels SP which configure a plurality of pixels and a driving circuit for driving the plurality of sub pixels SP may be disposed.

The plurality of sub pixels SP are minimum units which configure the active area AA, and the plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another thereof may be a green sub-pixel, and the other thereof may be a blue sub-pixel. In some exemplary embodiments, plurality of sub-pixels may further include a fourth sub-pixel, and the fourth sub-pixel may be a white sub-pixel A type of each of the plurality of sub-pixels is an example, and exemplary embodiments of the present disclosure are not limited thereto.

For example, the plurality of subpixels of the pixel may be variously modified in colors and configurations, as necessary. For example, the plurality of subpixels may include red, green, and blue subpixels, in which the red, green, and blue subpixels may be disposed in a repeated manner. Alternatively, the plurality of subpixels may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

Further more, a display element may be disposed in each of the plurality of sub pixels SP. For example, an organic light emitting diode which includes an anode, an organic emission layer, and a cathode may be disposed in each of the plurality of sub pixels SP, but it is not limited thereto. Further, the driving circuit for driving the plurality of sub pixels SP may include a driving element and a wiring line. For example, the driving circuit may be configured by a thin film transistor, a storage capacitor, a gate line, and a data line, but is not limited thereto.

The active layer of the thin film transistor may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The non-active area NA is an area where no image is displayed. The non-active area NA refers to an outer peripheral portion of the display panel PN surrounding the active area AA. In the non-active area NA, various wiring lines and circuits for driving the organic light emitting diode of the active area AA are disposed. For example, in the non-active area NA, a link line which transmits signals to the plurality of sub pixels SP and driving circuits of the active area AA or a driving IC (D-IC) such as a gate driver IC or a data driver IC may be disposed, but it is not limited thereto.

The non-display area NA includes a first non-display area NA1, a bending area BA, and a second non-display area NA2.

The first non-display area NA1 is an area surrounding the display area AA and extends from the display area AA. The bending area BA may extend from one side of the first non-display area NA1 and may be bent. The second non-active area NA2 is an area which extends from the bending area BA to be disposed below the active area AA.

In the meantime, referring to FIGS. 1A, 1B, and 3, the first non-active area NA and the second non-active area NA2 are disposed on the same plane as the active area AA or disposed to be parallel to the active area AA and maintain a flat state. For example, the first non-display area NA1 is disposed to be flat on the same plane as the display area AA and the second non-display area NA2 is disposed below the display area AA to be parallel to the display area AA and be flat. Therefore, the active area AA, the first non-active area NA1, and the second non-active area NA2 may be referred to as non-bending areas, but are not limited thereto.

Referring to FIGS. 1A and 1B, the driving integrated circuit (IC) D-IC is disposed in the second non-active area NA2. The driving IC D-IC supplies a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage. For exampler, based on the timing signal Vsync, Hsync, and DE received from the host system HS, the timing controller may generate a data timing control signal for controlling the operation timing of the data driver, and a gate timing control signal for controlling operation timing of the gate driver. Here, the horizontal synchronization signal Hsync is a signal representing a time taken to display one horizontal line of a screen and the vertical synchronization signal Vsync is a signal representing a time taken to display a screen of one frame. The data enable signal DE may correspond to a signal indicating a period for which a data voltage is supplied to the pixel. The driving IC D-IC supplies a data signal through the plurality of data lines. For example, in the second non-active area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the display panel PN in a chip on panel (COP) manner to be connected to the display panel PN or is disposed in a separate flexible film to be connected to the display panel PN in a chip on film (COF) manner. In the display device 100 according to the exemplary embodiment of the present disclosure, it is assumed that the driving IC D-IC is disposed in the COP manner, but it is not limited thereto.

Referring to FIG. 1B, as the display panel PN is bent, the driving IC D-IC disposed in the non-active area NA2 is disposed below the active area AA. For example, the driving IC D-IC and the printed circuit board connected to the pad unit of the display panel PN move to the rear surface of the display panel PN and overlap the display area AA. Therefore, as seen from the top of the display panel PN, circuit elements, such as the driving IC D-IC and the printed circuit board may not be visible. Accordingly, a size of the non-active area which is visible from the top of the display panel PN is reduced to implement a narrow bezel.

Referring to FIG. 2, the display device 100 according to the exemplary embodiment of the present disclosure includes a substrate 110, a lower buffer layer 111, a first transistor TR1, a storage capacitor Cst, a first gate insulating layer 112a, a first interlayer insulating layer 113a, an upper buffer layer 114, a second transistor TR2, a second gate insulating layer 112b, a second interlayer insulating layer 113b, a first connection electrode CE1, a first planarization layer 115a, a second connection electrode CE2, a second planarization layer 115b, a bank 116a, a spacer 116b, a light emitting diode 125, and an encapsulation layer 117.

The substrate 110 serves to support and protect components of the display device 100 disposed thereabove.

The substrate 110 is a component for supporting various components included in the display device 100 and may be formed of an insulating material. The substrate 110 includes a first substrate 110a, a second substrate 110b, and an inorganic insulating layer 110c. The inorganic insulating layer 110c may be disposed between the first substrate 110a and the second substrate 110b. As described above, the substrate 110 is configured by a triple layer of the first substrate 110a, the second substrate 110b, and the inorganic insulating layer 110c to minimize the moisture permeation from the outside. However, the substrate 110 may be disposed as a single layer, but is not limited thereto.

The first substrate 110a has rigidity and flexibility. The first substrate 110a may be a configuration which substantially supports components of the display device 100, among configurations of the substrate 110. For example, the first substrate 110a may include a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. For example, the first substrate 110a, for example, may be a flexible substrate which is formed of polyimide (PI), but is not limited thereto.

The inorganic insulating layer 110c is disposed on the entire surface on the first substrate 110a. The inorganic insulating layer 110c is formed of an inorganic insulating material. For example, the inorganic insulating layer 110c may be formed by a single layer of silicon nitride (SiNx) or silicon oxide (SiOx) or a multilayer thereof, but is not limited thereto. For example, the inorganic insulating layer 110c may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

The inorganic insulating layer 110c may be formed on the entire substrate 110, but is not limited thereto. For example, the inorganic insulating layer 110c may not be formed in the bending area BA or patterned in the bending area BA.

The second substrate 110b is disposed on the inorganic insulating layer 110c. The second substrate 110b has rigidity and flexibility. The second substrate 110b may be a configuration which substantially supports components of the display device 100, among configurations of the substrate 110, together with the first substrate 110a. For example, the second substrate 110b may include a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto, For example, the second substrate 110b may be a flexible substrate which is formed of polyimide (PI), but is not limited thereto.

The lower buffer layer 111 is disposed on the substrate 110. The lower buffer layer 111 is disposed below the first transistor TR1 to delay diffusion of moisture or oxygen which has permeated into the substrate 110, to the first transistor TR1.

The lower buffer layer 111 includes a first lower buffer layer 111a and a second lower buffer layer 111b. The lower buffer layer 111 is formed by a multiple layer including a first lower buffer layer 111a and a second lower buffer layer 111b. Therefore, even though the lower buffer layer 111 is referred to as a multi-buffer layer, the lower buffer layer 111 may be formed by a single layer or may be formed of a plurality of layers, other than two layers, but is not limited thereto.

For example, the first lower buffer layer 111a may be formed by a single layer of any one of amorphous silicon (a-Si), silicon nitride (SiNx), and silicon oxide (SiOx) or a multiple layer thereof, but is not limited thereto.

For example, the second lower buffer layer 111b may be formed by a single layer of any one of amorphous silicon (a-Si), silicon nitride (SiNx), and silicon oxide (SiOx) or a multiple layer thereof, but is not limited thereto.

For example, the first lower buffer layer 111a and the second lower buffer layer 111b may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

The first transistor TR1 is disposed on the lower buffer layer 111. The first transistor TR1 may include a first active layer A1, a first gate electrode G1, a first source electrode S1, and a first drain electrode D1. However, depending on the design of the pixel circuit, the first source electrode S1 may serve as the first drain electrode D1 and the first drain electrode D1 serves as the first source electrode S1.

The first active layer A1 is disposed on the lower buffer layer 111. The first active layer A1 may include low temperature polycrystalline silicon (LTPS), such as amorphous silicon or polycrystalline silicon.

For example, the first active layer A1 may include a low-temperature polycrystalline silicon LTPS. For example, since the polysilicon material has a high mobility (100 cm2/Vs or higher), an energy power consumption is low and a reliability is high, so that the polysilicon material may be applied to a gate driver for a driving element which drives for a transistor for a light emitting diode and/or a multiplexer MUX. Therefore, the first active layer A1 including a low-temperature polycrystalline silicon LTPS is applied as an active layer of the driving transistor, but is not limited thereto.

For example, the first active layer A1 may include a channel region in which a channel is formed when the first transistor TR1 is driven and a source region and a drain region on both sides of the channel region. The source region refers to a part of the first active layer A1 which is connected to the first source electrode S1 and the drain region refers to a part of the first active layer A1 which is connected to the first drain electrode D1. For example, the source region and the drain region are configured by ion-doping (impurity doping) of the first active layer A1. The source region and the drain region may be generated by doping ions into the polycrystalline silicon material and the channel region may refer to a part in which the ions are not doped, but the polycrystalline silicon material remains.

The first gate insulating layer 112a is disposed on the first active layer A1. The first gate insulating layer 112a may be configured by a single layer of silicon nitride (SiNx) or silicon oxide (SiOx) or a multilayer thereof. In the first gate insulating layer 112a, a contact hole through which the first source electrode S1 and the first drain electrode D1 of the first transistor TR1 are connected to the source region and the drain region of the first active layer A1 of the first transistor TR1, respectively, may be formed.

The first gate electrode G1 of the first transistor TR1 may be disposed on the first gate insulating layer 112a.

For example, the first gate electrode G1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The first gate electrode G1 may be formed on the first gate insulating layer 112a so as to overlap the channel region of the first active layer A1 of the first transistor TR1.

In the meantime, a first capacitor electrode C1 of the storage capacitor Cst may be disposed on the first gate insulating layer 112a. For example, the first capacitor electrode C1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The first capacitor electrode C1 may be omitted based on a driving characteristic of the display device 100 and a structure and a type of the transistor. The first gate electrode G1 and the first capacitor electrode C1 may be formed by the same process. Further, the first gate electrode G1 and the first capacitor electrode C1 may be formed of the same material on the same layer.

The first interlayer insulating layer 113a may be disposed on the first gate insulating layer 112a and the first gate electrode G1. In the first interlayer insulating layer 113a, a contact hole for exposing the first source region and the first drain region of the first active layer A1 of the first transistor TR1 may be formed. For example, the first interlayer insulating layer 113a may be configured by a single layer of silicon nitride (SiNx) or silicon oxide (SiOx) or a multiple layer thereof.

A second capacitor electrode C2 of the storage capacitor Cst may be disposed on the first interlayer insulating layer 113a. The second capacitor electrode C2 may be formed by a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof.

The second capacitor electrode C2 may be formed on the first interlayer insulating layer 113a so as to overlap the first capacitor electrode C1. Further, the second capacitor electrode C2 may be formed of the same material as the first capacitor electrode C1. The second capacitor electrode C2 may be omitted based on a driving characteristic of the display device 100 and a structure and a type of the transistor, but is not limited thereto.

The upper buffer layer 114 is disposed on the first interlayer insulating layer 113a. The upper buffer layer 114 includes a first upper buffer layer and a second upper buffer layer. The upper buffer layer 114 is formed as a multiple layer including a first upper buffer layer and a second upper buffer layer. Therefore, even though the upper buffer layer 114 is referred to as a multi-buffer layer, the upper buffer layer 114 may be formed as a single layer or may be formed of a plurality of layers, other than two layers, but is not limited thereto.

For example, the first upper buffer layer may be formed by a single layer of any one of amorphous silicon (a-Si), silicon nitride (SiNx), and silicon oxide (SiOx), or a multi-layer thereof, but is not limited thereto.

For example, the second upper buffer layer may be formed by a single layer of any one of amorphous silicon (a-Si), silicon nitride (SiNx), and silicon oxide (SiOx), or a multi-layer thereof, but is not limited thereto.

For example, the first upper buffer layer and the second upper buffer layer may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

The second transistor TR2 is disposed on the upper buffer layer 114. The second transistor TR2 may include a second active layer A2, a second gate electrode G2, a second source electrode S2, and a second drain electrode D2. However, depending on the design of the pixel circuit, the second source electrode S2 may serve as a drain electrode and the second drain electrode D2 may serve as a second source electrode S2.

The second active layer A2 is disposed on the upper buffer layer 114. The second active layer A2 includes an oxide semiconductor material formed of metal oxide, such as indium-gallium-zinc-oxide (IGZO), indium-zinc-oxide (IZO), indium-gallium-tin-oxide (IGTO), or indium-gallium-oxide (IGO).

For example, the second active layer A2 may be formed of an oxide semiconductor. The oxide semiconductor material has a larger band gap than a silicon material so that electrons cannot jump over the band gap in an off state. Therefore, the oxide semiconductor material has a low off-current. Therefore, the transistor including an active layer which is formed of an oxide semiconductor is suitable for a switching transistor which maintains short on-time and long off-time, but is not limited thereto.

For example, the second active layer A2 may include a channel region in which a channel is formed when the second transistor TR2 is driven and a source region and a drain region on both sides of the channel region. The source region refers to a part of the second active layer A2 which is connected to the second source electrode S2 and the drain region refers to a part of the second active layer A2 which is connected to the second drain electrode D2. For example, the source region and the drain region are configured by ion-doping (impurity doping) of the second active layer A2. The source region and the drain region may be generated by doping ions into the oxide semiconductor material and the channel region may refer to a part in which the ions are not doped, but the oxide semiconductor material remains.

The second gate insulating layer 112b may be disposed on the second active layer A2. The second gate insulating layer 112b may be configured as a single layer of silicon nitride (SiNx) or silicon oxide (SiOx) or a multi-layer thereof. In the second gate insulating layer 112b, a contact hole through which the second source electrode S2 and the second drain electrode D2 of the second transistor TR2 are connected to the source region and the drain region of the second active layer A2, respectively, may be formed.

The second gate electrode G2 of the second transistor TR2 is disposed on the second gate insulating layer 112b.

For example, the second gate electrode G2 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The second gate electrode G2 may be formed on the second gate insulating layer 112b so as to overlap the channel region of the second active layer A2 of the second transistor TR2.

The second interlayer insulating layer 113b may be disposed on the second gate insulating layer 112b and the second gate electrode G2. The second interlayer insulating layer 113b may be configured as a single layer of silicon nitride (SiNx) or silicon oxide (SiOx) or a multi-layer thereof.

A first source electrode S1 and a first drain electrode D1 of the first transistor TR1, a second source electrode S2 and a second drain electrode D2 of the second transistor TR2, and the first connection electrode CE1 are disposed on the second interlayer insulating layer 113b.

The first source electrode S1 and the first drain electrode D1 may be electrically connected to the first active layer A1 of the first transistor TR1 through contact holes of the first gate insulating layer 112a, the first interlayer insulating layer 113a, the upper buffer layer 117, the second gate insulating layer 112b, and the second interlayer insulating layer 113b.

The second source electrode S2 and the second drain electrode D2 may be electrically connected to the second active layer A2 of the second transistor TR2 through contact holes of the second gate insulating layer 112b and the second interlayer insulating layer 113b.

The first source electrode S1, the first drain electrode D1, the second source electrode S2, and the second drain electrode D2 may be formed of a single layer or a multi-layer formed of any one of, for example, molybdenum (Mo), copper (Cu), titanium (Ti), aluminum (Al), chrome (Cr), gold (Au), nickel (Ni), and neodymium (Nd) or an alloy thereof, but are not limited thereto.

The first connection electrode CE1 may be electrically connected to the second drain electrode D2 of the second transistor TR2. Further, the first connection electrode CE1 may be electrically connected to the second capacitor electrode C2 of the storage capacitor Cst through the contact holes formed in the upper buffer layer 114 and the second interlayer insulating layer 113b. That is, the first connection electrode CE1 may serve to electrically connect the second capacitor electrode C2 of the storage capacitor Cst and the second drain electrode D2 of the second transistor TR2 to each other.

In the meantime, the first connection electrode CE1 may be formed of the same material by the same process as the first source electrode S1 and the first drain electrode D1 of the first transistor TR1 and the second source electrode S2 and the second drain electrode D2 of the second transistor TR2. For example, the first connection electrode CE1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

Further, the first connection electrode CE1 may be integrally formed to be connected to the second drain electrode D2 of the second transistor TR2, but is not limited thereto.

In the first transistor TR1 and the second transistor TR2, light shielding layers LS are disposed below the first active layer A1 and the second active layer A2, respectively. The light shielding layer LS is disposed so as to overlap the first active layer A1 between the substrate 110 and the lower buffer layer 111 and is disposed so as to overlap the second active layer A2 between the first interlayer insulating layer 113a and the upper buffer layer 114. Therefore, the light shielding layer LS may be insulated from the first active layer A1 and the second active layer A2.

The light shielding layer LS may be formed of a metal material having low light transmittance and reflect light which is incident onto the first active layer A1 and the second active layer A2, below the first active layer A1 and the second active layer A2. The light shielding layer LS may shield light which is incident onto the first active layer A1 and the second active layer A2 and protect the first active layer A1 and the second active layer A2.

For example, the light shielding layer LS is referred to as a bottom shield metal (BSM), but is not limited thereto. Specifically, the light shielding layer LS may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The first planarization layer 115a may be disposed on the first connection electrode CE1, the first source electrode S1 and the first drain electrode D1 of the first transistor TR1, the second source electrode S2 and the second drain electrode D2 of the second transistor TR2, and the second interlayer insulating layer 113b.

The first planarization layer 115a may be an organic layer which planarizes and protects upper portions of the first transistor TR1 and the second transistor TR2. For example, the first planarization layer 115a may be formed of an organic material such as acryl resin, epoxy resin, phenolic resin, polyamide resin, or polyimide resin.

The second connection electrode CE2 is disposed on the first planarization layer 115a. The second connection electrode CE2 may be connected to the second drain electrode D2 of the second transistor TR2 through the contact hole of the first planarization layer 115a. Therefore, the second connection electrode CE2 may be configured to electrically connect the second transistor TR2 and the light emitting diode 125.

The second connection electrode CE2 may be formed of a single layer or a multiple layer formed of any one of, for example, molybdenum (Mo), copper (Cu), titanium (Ti), aluminum (Al), chrome (Cr), gold (Au), nickel (Ni), and neodymium (Nd) or an alloy thereof, but is not limited thereto.

The second planarization layer 115b is disposed on the first planarization layer 115a and the second connection electrode CE2. A top surface of the second planarization layer 115b has a surface parallel to the substrate 110. Therefore, the second planarization layer 115b may planarize a step which may be caused by the components disposed therebelow. For example, the second planarization layer 115b may be formed of an organic material, such as acryl resin, epoxy resin, phenolic resin, polyamide resin, or polyimide resin, but is not limited thereto.

The light emitting diode 125 is disposed on the second planarization layer 115b.

The light emitting diode 125 includes an anode 121, an emission layer 122, and a cathode 123.

The anode 121 is disposed on the second planarization layer 115b. The anode 121 may be connected to the second connection electrode CE2 through a contact hole of the second planarization layer 115b and may be electrically connected to the second transistor TR2. The anode 121 may be formed of a metallic material.

When the display device 100 is a top emission type in which light emitted from the light emitting diode 125 is emitted above the substrate 110 on which the light emitting diode 125 is disposed, the anode 121 may include a reflective layer and a transparent conductive layer disposed on the reflective layer. The transparent conductive layer may be formed of transparent conductive oxide such as indium tin oxide (ITO) or indium zinc oxide (IZO) and the reflective layer may be formed of silver (Ag), aluminum (Al), gold (Au), molybdenum (Mo), tungsten (W), chrome (Cr), or an alloy thereof, but they are not limited thereto.

The anode 121 is disposed so as to correspond to each of the plurality of sub pixels SP. The anode 121 is disposed so as to cover the second planarization layer 115b. The anode 121 may be disposed along the shape of the second planarization layer 115b. That is, the anode 121 may be disposed to be flat on the top surface of the second planarization layer 115b.

The bank 116a is disposed on the anode 121. The bank 116a may be disposed while covering an end of the anode 121. A part of the bank 116a corresponding to an emission area of the sub pixel SP may be open. A part of the anode 121 may be exposed through the open part of the bank 116a (hereinafter, referred to as an open area). At this time, the bank 116a may be formed of an inorganic insulating material, such as silicon nitride (SiNx) or silicon oxide (SiOx), or an organic insulating material, such as benzocyclobutene resin, acrylic resin or imide resin, but is not limited thereto. The spacer 116b may be further disposed on the bank 116a.

The emission layer 122 is disposed on the anode 121 and the bank 116a. The emission layer 122 may be disposed in the open area of the bank 116a and in the vicinity of the open area of the bank 116a. Therefore, the emission layer 122 may be disposed on the anode 121 exposed through the open area of the bank 116a.

The emission layer 122 may include a plurality of organic material layers. For example, the emission layer 122 may include an organic material layer such as a hole injection layer, a hole transport layer, an electron transport layer, and an electron injection layer. In the meantime, when the emission layer 122 emits white light, light emitted from the emission layer 122 may be converted into light with various colors by a plurality of color filters, but is not limited thereto. The emission layer 122 may include an emission material layer and a plurality of organic layers which are partitioned by the bank 116a.

The cathode 123 is disposed on the emission layer 122. The cathode 123 supplies electrons to the emission layer 122 so that the cathode may be formed of a conductive material having a low work function. The cathode 123 may be formed as one layer over the plurality of sub pixels SP. That is, the cathodes 123 of the plurality of sub pixels SP may be connected to be integrally formed.

For example, the cathode 123 may be formed of a transparent conductive material such as indium tin oxide (ITO) and indium zinc oxide (IZO) or ytterbium (Yb) alloy and may further include a metal doping layer, but is not limited thereto.

The encapsulation layer 117 is disposed on the light emitting diode 125.

The encapsulation layer 117 may have a multi-layered structure including a first encapsulation layer 117a, a second encapsulation layer 117b, and a third encapsulation layer 117c. However, the encapsulation layer may be formed with a single layer structure, but is not limited thereto.

The first encapsulation layer 117a and the third encapsulation layer 117c may be formed of inorganic materials and the second encapsulation layer 117b may be formed of an organic material. The second encapsulation layer 117b may be the thickest among the first encapsulation layer 117a, the second encapsulation layer 117b, and the third encapsulation layer 117c. The second encapsulation layer 117b may planarize an upper portion of the light emitting diode 125.

The first encapsulation layer 117a may be disposed on the cathode 123 and may be disposed to be most adjacent to the light emitting diode 121. The first encapsulation layer 117a may be formed of an inorganic insulating material on which low-temperature deposition can be performed. For example, the first encapsulation layer 117a may be configured by silicon nitride (SiNx), silicon oxide (SiOx), silicon oxynitride (SiON), or aluminum oxide (Al2O3), but is not limited thereto.

The first encapsulation layer 117a is deposited under a low temperature atmosphere so that during the deposition process, the damage of the light emitting layer 122 including an organic material which is vulnerable to the high temperature atmosphere may be suppressed.

The second encapsulation layer 117b is disposed on the first encapsulation layer 117a. The second encapsulation layer 117b may be disposed to have a smaller area than that of the first encapsulation layer 117a. In this case, the second encapsulation layer 117b may be formed to expose both ends of the first encapsulation layer 117a. The second encapsulation layer 117b may serve as a buffer to relieve stress between the layers due to bending of the display device 100 and to enhance planarization performance.

For example, the second encapsulation layer 117b may be formed of an organic insulating material, such as acrylic resin, epoxy resin, polyimide, polyethylene, or silicon oxy carbon (SiOC). For example, the second encapsulation layer 117b may be formed by an inkjet method, but is not limited thereto.

The third encapsulation layer 117c may be formed above the substrate 110 on which the second encapsulation layer 117b is formed so as to cover upper surfaces and side surfaces of the second encapsulation layer 117b and the first encapsulation layer 117a. At this time, the third encapsulation layer 117c may minimize or block the permeation of external moisture or oxygen into the first encapsulation layer 117a and the second encapsulation layer 117b. For example, the third encapsulation layer 117c may be configured by an inorganic insulating material, such as silicon nitride (SiNx), silicon oxide (SiOx), silicon oxynitride (SiON), or aluminum oxide (Al2O3), but may be limited thereto.

Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

Even though not illustrated in the drawing, a touch sensing layer may be disposed on the encapsulation layer 117.

The touch sensing layer may include a touch buffer layer, a touch interlayer insulating layer, and a touch electrode. The touch electrode may include a touch sensor metal and a bridge metal which are located on different layers.

For example, the touch buffer layer is disposed on the third encapsulation layer 117c and the bridge metal is disposed on the touch buffer layer. The touch interlayer insulating layer is disposed on the bridge metal and the touch sensor metal is disposed on the touch interlayer insulating layer.

The touch buffer layer and the touch interlayer insulating layer may be formed of, for example, an inorganic insulating material or an organic insulating material. Therefore, the touch buffer layer and the touch interlayer insulating layer may minimize a step in a location where the touch electrode is disposed and may be formed to electrically insulate the touch sensor metal and the bridge metal from each other.

Referring to FIGS. 1B, 3 and 4, the cover window 120 is disposed on the front surface of the display panel PN. The cover window 120 may be a component which is exposed to the outer periphery of the display device 100 and protect the display device 100 from external shock or scratches. Further, the cover window 120 may protect the display device 100 from moisture and the like permeating from the outside. The cover window 120 may be formed of a glass or a plastic material having a flexibility, but is not limited thereto.

A polarizer POL is disposed between the display panel PN and the cover window 120. The polarizer POL may be disposed on the front surface of the display panel PN. The polarizer POL selectively transmits light to reduce the reflection of external light which is incident onto the display panel PN. Specifically, the display panel PN includes various metal materials applied to the semiconductor element, the wiring line, and the organic light emitting diode. Therefore, the external light incident onto the display panel PN may be reflected from the metal material so that the visibility of the display device 100 may be reduced due to the reflection of the external light. In contrast, when the polarizer POL is disposed, the polarizer POL suppresses the reflection of the external light so that the outdoor visibility of the display device 100 may be increased. However, the polarizer POL may be omitted depending on an implementation example of the display device 100, but it is not limited thereto.

A plurality of adhesive layers AD1, AD2, AD3, AD4, AD5, AD6, AD7, and AD8 may serve to bond individual components of the display device 100 to each other and may be disposed between the display panel PN and the cover window 120 and between the display panel PN and the frame 150.

A third adhesive layer AD3 is disposed between the polarizer POL and the cover window 120 and a first adhesive layer AD1 is disposed between the polarizer POL and the display panel PN. The third adhesive layer AD3 bonds the cover window 120 and the polarizer POL and the first adhesive layer AD1 bonds the polarizer POL and the display panel PN. As a result, the first adhesive layer AD1 and the third adhesive layer AD3 bond the display panel PN and the cover window 120. The first adhesive layer AD1 and the third adhesive layer AD3 may be formed as transparent adhesive layers so that an image of the display panel PN is visible. For example, the first adhesive layer AD1 and the third adhesive layer AD3 may be formed of an optical clear adhesive (OCA) or a pressure sensitive adhesive (PSA), but are not limited thereto.

The back plate 130 is disposed below the display panel PN. The back plate 130 may be disposed so as to support the display panel PN. For example, when the substrate of the display panel PN is formed of a plastic material, such as polyimide, due to the flexible property, a separate component for supporting the substrate may be necessary. Therefore, a support substrate which is formed of glass is disposed below the substrate to perform a manufacturing process of the display device 100 and the support substrate may be separated to be released after completing the manufacturing process. However, a component for supporting the substrate is necessary even after releasing the support substrate, so that a back plate 130 for supporting the substrate may be disposed below the display panel PN.

The back plate 130 may include a plastic material. For example, the back plate 130 may be formed of a plastic thin film formed of polyimide (PI), polyethylene naphthalate (PEN), polyethylene terephthalate (PET), or a combination of the polymers.

The second adhesive layer AD2 is disposed between the display panel PN and the back plate 130. The second adhesive layer AD2 may bond the display panel PN and the back plate 130. The second adhesive layer AD2 may be formed of an optical clear adhesive (OCA) or a pressure sensitive adhesive (PSA), but is not limited thereto.

The metal plate 140 is disposed below the back plate 130. The metal plate 140 may protect the components of the display device 100 from external shocks. Further, the metal plate 140 serves as an earth to suppress the static electricity entering the display device 100 or easily discharge residual charges accumulated in the display device 100 to the outside. Further, the metal plate 140 easily discharges heat generated in the display device 100 to the outside. The metal plate 140 may be formed of a metal material having excellent thermal conductivity, electrical conductivity, and mechanical rigidity. For example, the metal plate 140 may be configured by copper (Cu) or stainless steel (SUS), but is not limited thereto.

The fourth adhesive layer AD4 is disposed between the back plate 130 and the metal plate 140. The fourth adhesive layer AD4 may bond the back plate 130 and the metal plate 140 to each other. The fourth adhesive layer AD4 may be formed of an optical clear adhesive (OCA) or a pressure sensitive adhesive (PSA), but is not limited thereto.

Referring to FIG. 3, an additional back plate 130A and an additional metal plate 140A are disposed below the metal plate 140 corresponding to the bending area BA.

The additional back plate 130A and the additional metal plate 140A supplement the rigidity of the display panel PN disposed in the second non-active area NA2. In the meantime, the additional back plate 130A and the additional metal plate 104A may be disposed so as not to overlap the bending area BA. Therefore, the thicknesses of the configurations disposed in the bending area BA are minimized and a neutral plane of the bending area BA is easily controlled to ensure the flexibility of the bending area.

A sixth adhesive layer AD6 is disposed between the metal plate 140 and the additional metal plate 140A and a seventh adhesive layer AD7 is disposed between the additional metal plate 140A and the additional back plate 130A. The sixth adhesive layer AD6 bonds between the metal plate 140 and the additional metal plate 140A and the seventh adhesive layer AD7 bonds between the additional metal plate 140A and the additional back plate 130A. For example, the sixth adhesive layer AD6 and the seventh adhesive layer AD7 may be formed of a pressure sensitive adhesive (PSA), but are not limited thereto.

The second non-active area NA2 of the display panel PN is disposed below the additional back plate 130A. An eighth adhesive layer AD8 is disposed between the additional back plate 130A and the second non-active area NA2 of the display panel PN. The eighth adhesive layer AD8 bonds between the additional back plate 130A and the second non-active area NA2 of the display panel PN. For example, the eighth adhesive layer AD8 may be formed of an optical clear adhesive (OCA) or a pressure sensitive adhesive (PSA), but is not limited thereto.

Referring to FIG. 3, side surfaces of the plurality of adhesive layers AD1, AD2, AD3, AD4, AD6, AD7, and AD8 in the first non-active area NA1 adjacent to the bending area BA may be flat at the interface with the molding member 160. For example, the side surfaces of the plurality of adhesive layers AD1, AD2, AD3, AD4, AD6, AD7, and AD8 adjacent to the bending area BA may be flat at the interface with the molding member 160. Specifically, a process of cutting outer peripheries of the first non-active area NA1, the bending area BA, the second non-active area NA2 of the display panel PN excluding the bending area BA, for example, a trimming process is performed before bonding the cover window 120, to form an outer peripheral shape of the display panel PN. Therefore, the first non-active area NA1 adjacent to the bending area BA corresponds to an area on which the trimming process is not performed so that side surfaces of the plurality of adhesive layers AD1, AD2, AD3, AD4, AD6, AD7, and AD8 are not deformed by the trimming process.

Referring to FIGS. 1B and 4, the frame 150 is disposed below the metal plate 130. The frame 150 may be disposed along an outer periphery of the display device 100 below the metal plate 140. Therefore, the frame 150 reinforces the rigidity of the outer periphery of the display device 100 while covering the outer periphery of the display device 100. Further, the frame 150 is partially exposed from the molding member 160 as illustrated in FIG. 1B to serve as a fastening unit with the component disposed below the frame 150.

For example, the frame 150 may be formed of plastic formed by polyimide (PI), polyethylene naphthalate (PEN), polyethylene terephthalate (PET), or combinations of these polymers or a metal, such as copper (Cu) or stainless steel (SUS) to reinforce the rigidity of the outer periphery of the display device 100. However, it is not limited thereto.

A fifth adhesive layer AD5 is disposed between the metal plate 140 and the frame 150. The fifth adhesive layer AD5 bonds the metal plate 140 and the frame 150. For example, the fifth adhesive layer AD5 may be formed of an optical clear adhesive (OCA) or a pressure sensitive adhesive (PSA), but is not limited thereto.

The molding member 160 seals the cover window 120, the display panel PN, the back plate 130, the metal plate 140, and the frame 150. Specifically, the molding member 140 may be disposed so as to surround a bottom of the cover window 120, a side surface of the display panel PN, a side surface of the back plate 130, a side surface of the metal plate 140, and a side surface and a part of a bottom surface of the frame 150. The molding member 160 may be disposed so as to cover the side surface of the display panel PN below the cover window 120. At this time, the molding member 160 may be disposed so as to cover the side surfaces of the plurality of adhesive layers AD1, AD2, AD3, AD4, and AD5 disposed between the cover window 120 and the display panel PN and between the display panel PN and the frame 150. The molding member 160 may suppress the permeation of the moisture or oxygen into the display device 100. Further, the molding member 160 may protect components of the display device 100 and relieve shocks applied to the display device 100.

For example, the molding member 160 may be formed by a process of removing a mold, after filling and curing a mold which is disposed to surround a side surface of the cover window 120 and expose a side surface of the display panel PN, a side surface of the back plate 130, a side surface of the metal plate 140, a side surface of the frame 150, and a part of a bottom surface of the frame 150 with a material for forming the molding member 160. However, the method of forming the molding member 160 is not limited thereto.

The molding member 160 may be formed of one or more materials of, for example, acrylic resin, epoxy resin, phenolic resin, polyamides resin, polyimides resin, unsaturated polyesters resin, polyphenylene resin, polyphenylenesulfides resin, and benzocyclobutene, but is not limited thereto.

In the present disclosure, a side surface of some of the plurality of adhesive layers AD1, AD2, AD3, AD4, and AD5 in the first non-active area NA1 which is not adjacent to the bending area BA may have an inwardly concave shape in a part of the interface with the molding member 160. Specifically, the side surfaces of the first adhesive layer AD1 and the second adhesive layer AD2 are inwardly concave at the interface with the molding member 160. That is, the interfaces between the first adhesive layer AD1 and the second adhesive layer AD2 disposed on a top and a bottom of the display panel PN and the molding member 160 may protrude toward the first adhesive layer AD1 and the second adhesive layer AD2, but not limited thereto.

Before bonding the cover window 120, a process of cutting an outer periphery of the first non-active area NA1 of the display panel PN excluding the bending area BA, for example, a trimming process is performed. The trimming process is a process for separating the display panel in the unit of cells along the shape of the display panel. At this time, during the trimming process, laser is used so that side surfaces of the first adhesive layer AD1 and the second adhesive layer AD2 may be deformed due to the laser. Therefore, side surfaces of the first adhesive layer AD1 and the second adhesive layer AD2 are deformed to be inwardly concave by the laser and serve as a barrier with the deformed side surface shape.

After the trimming process, a bonding process of the cover window 120, the metal plate 140, and the frame 150 are sequentially performed. Therefore, the side surfaces of the third adhesive layer AD3, the fourth adhesive layer AD4, and the fifth adhesive layer AD5 are not deformed due to the trimming process. Accordingly, the side surfaces of the third adhesive layer AD3, the fourth adhesive layer AD4, and the fifth adhesive layer AD5 are flat at the interface with the molding member 160.

Hereinafter, various shapes of the side surfaces of the first adhesive layer AD1 and the second adhesive layer AD2 will be described as an example with reference to FIGS. 5A and 5B.

Referring to FIG. 5A, the side surface of the first adhesive layer AD1 is inwardly concave at the interface with the molding member 160. The side surface of the first adhesive layer AD1 has an irregular shape AD_D1 which is inwardly concave. That is, the interface of the first adhesive layer AD1 and the molding member 160 and the interface of the molding member 160 and the second adhesive layer AD2 may protrude toward the adhesive layer which has an irregular shape.

Referring to FIG. 5B, the side surface of the first adhesive layer AD1 is inwardly concave at the interface with the molding member 160. The side surface of the first adhesive layer AD1 has an embossing shape AD_D2 which is inwardly concave. That is, the interface of the first adhesive layer AD1 and the molding member 160 and the interface of the molding member 160 and the second adhesive layer AD2 may protrude toward the adhesive layer which has an embossing shape.

In the meantime, referring to FIGS. 1A and 1B, the plurality of adhesive layers AD1, AD2, AD3, AD4, AD6, AD7, and AD8 in the first non-active area NA1 adjacent to the bending area BA has a flat shape at the interface with the molding member 160. Further, the plurality of adhesive layers AD1, AD2, AD3, AD4, and AD5 in the first non-active area NA1 which is not adjacent to the bending area BA has a shape which is inwardly concave in the first adhesive layer AD1 and the second adhesive layer AD2 at the interface with the molding member 160.

For example, referring to FIGS. 1A and 1B, if a portion where the bending area BA is located, among four surfaces of the display device 100, is defined as a top, a bottom, a left side, and a right side are defined with respect to the top. At this time, the plurality of adhesive layers AD1, AD2, AD3, AD4, and AD5 in the first non-active area NA1 on the bottom, the left side, and the right side of the display device 100 has a shape which is inwardly concave in the first adhesive layer AD1 and the second adhesive layer AD2 at the interface with the molding member 160. Further, the plurality of adhesive layers AD1, AD2, AD3, AD4, AD6, AD7, and AD8 in the first non-active area NA1 on the top has a flat shape at the interface with the molding member 160. Here, the first non-active area NA1 on the top corresponds to an area on which the trimming process is not performed so that side surfaces of the plurality of adhesive layers AD1, AD2, AD3, AD4, AD6, AD7, and AD8 are not deformed by the trimming process. Accordingly, the plurality of adhesive layers AD1, AD2, AD3, AD4, AD6, AD7, and AD8 in the first non-active area NA1 on the top may be flat at the interface with the molding member 160.

More specifically, in the first non-active area NA1 on the bottom, the left side, and the right side of the display device 100, the side surface of the first adhesive layer AD1 and the side surface of the second adhesive layer AD2 have an inwardly concave shape at the interface with the molding member 160. Further, a side surface of the third adhesive layer AD3, a side surface of the fourth adhesive layer AD4, and a side surface of the fifth adhesive layer AD5 have a flat shape at the interface with the molding member 160.

In the first non-active area NA1 on the bottom, the left side, and the right side, the side surface of the first adhesive layer AD1 and the side surface of the second adhesive layer AD2 are deformed due to the laser during the trimming process to have an inwardly concave shape at the interface with the molding member 160. Further, the bonding process of the cover window 120, the metal plate 140, and the frame 150 are performed after the trimming process so that the side surface of the third adhesive layer AD3, the side surface of the fourth adhesive layer AD4, and the side surface of the fifth adhesive layer AD5 are not affected by the trimming process to have a flat shape at the interface with the molding member 160.

The plurality of adhesive layers AD1, AD2, AD3, AD4, AD6, AD7, and AD8 in the first non-active area NA1 on the top may be flat at the interface with the molding member 160. That is, in the non-active area NA on the top which is adjacent to the bending area BA, the interface of the molding member 160 and the plurality of adhesive layers AD1, AD2, AD3, AD4, AD6, AD7, and AD8 has the flat shape. In other words, in the non-active area NA adjacent to the bending area BA, the interface of the first adhesive layer AD1 and the second adhesive layer AD2 disposed on the top and the bottom of the display panel PN and the molding member 160 may have a flat shape. As described above, this is because the first non-active area NA1 on the top is an area on which the trimming process is not performed so that side surfaces of the plurality of adhesive layers AD1, AD2, AD3, AD4, AD6, AD7, and AD8 are not deformed by the trimming process and have a flat shape at the interface with the molding member 160.

In the display device, a separate cover unit may be disposed below the cover window so as to protect the components of the display device, such as a display panel. However, when a separate cover unit is disposed, in order to minimize or at least reduce the interference between the display panel and the cover unit, the cover unit is coupled to be spaced apart from the display panel with a predetermined distance. Therefore, in the display device in which a separate cover unit is disposed below the cover window, it is difficult to implement a narrow bezel due to the space between the display panel and the cover unit.

Therefore, in the display device 100, the molding member 160 which seals the components of the display device 100 is disposed below the cover window 120 to minimize or at least reduce the size of the bezel area.

However, when a process of heating and cooling is repeated on the display device, the components of the display panel PN of the display device 100 expand and contract and the molding member 160 also expand and contract. If this process is repeated, a stress is generated on the display panel PN so that the display panel PN is cracked, which causes the defect of the display device 100 due to the crack.

Accordingly, in the display device 100 according to the exemplary embodiment of the present disclosure, a part of an interface of a side surface of some of the plurality of adhesive layers AD1, AD2, AD3, AD4, and AD5 and the molding member 160 has an inwardly concave shape. Accordingly, the stress of the display panel PN due to the contraction and expansion of the molding member 160 which may be generated under the reliability environment may be reduced or minimized. Specifically, a side surface of some of the plurality of adhesive layers AD1, AD2, AD3, AD4, and AD5 disposed between the display panel PN and the cover window 120 and between the display panel PN and the frame 150 has an inwardly concave shape in a part of the interface with the molding member 160. That is, the interface between the first adhesive layer AD1 and the second adhesive layer AD2 disposed on the top and the bottom of the display panel PN and the molding member 160 may form a shape protruding toward the first adhesive layer AD1 and the second adhesive layer AD2 to reduce or minimize the stress of the display panel PN due to the contraction and expansion of the molding member 160. By doing this, in the display device 100 according to the exemplary embodiment of the present disclosure, a part of interfaces of side surfaces of the plurality of adhesive layers AD1, AD2, AD3, AD4, and AD5 and the molding member 160 has an inwardly concave shape. As shown in FIG. 4, in an area of the first non-active area adjacent to the bending area, the side surfaces of the plurality of adhesive layers AD3, AD4 and AD5 have a flat shape at the interface with the molding member and in other area of the first non-active area, the side surfaces of the plurality of adhesive layers AD1 and AD2 have an inwardly concave shape at a part of the interface with the molding member. Accordingly, the stress due to the contraction and expansion of the molding member 160 is relieved to suppress the crack generated in the display panel PN, thereby reducing or minimizing the defect the display device 100.

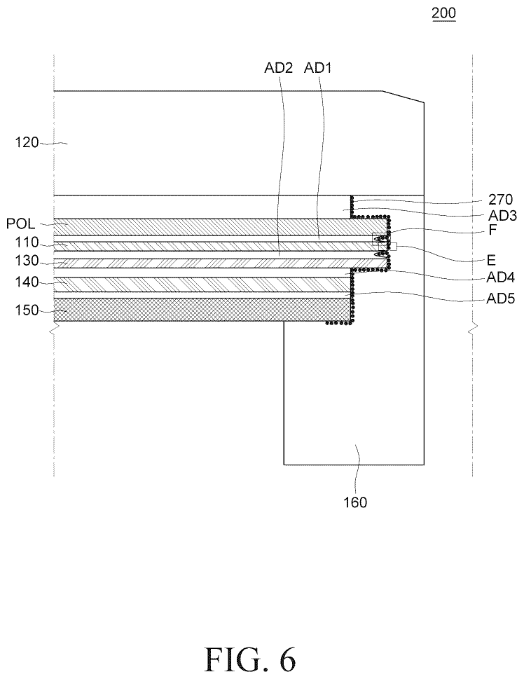

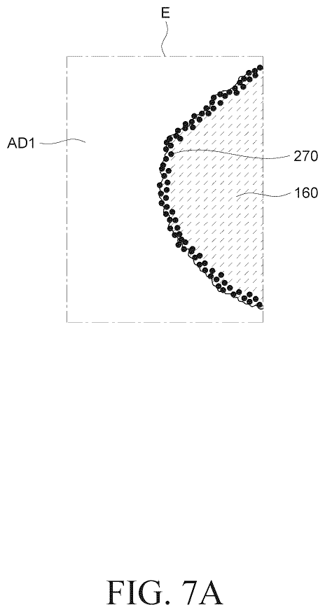

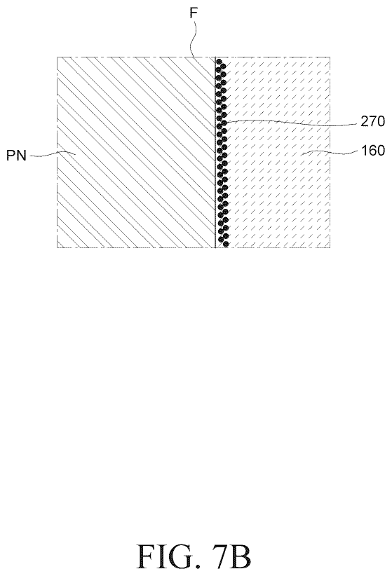

FIG. 6 is a cross-sectional view of a display device according to another exemplary embodiment of the present disclosure. FIG. 7A is an enlarged cross-sectional view of an area E of FIG. 6 according to an exemplary embodiment of the present disclosure. FIG. 7B is an enlarged cross-sectional view of an area F of FIG. 6 according to an exemplary embodiment of the present disclosure. In FIG. 6, for the convenience of description, among components of a display device 200, a display panel PN, a cover window 120, a polarizer POL, a back plate 130, a metal plate 140, a frame 150, and a molding member 160 are illustrated. The display device 200 of FIG. 6 further includes a barrier layer 270, but the others are the same as the display device 100 of FIGS. 1A to 4 so that a redundant description will be omitted.

Referring to FIG. 6, the barrier layer 270 may be disposed in the first non-active area NA1 which is not adjacent to the bending area BA.

The barrier layer 270 serves as a barrier between side surfaces of the polarizer POL, a side surface of the display panel PN, a side surface of the back plate 130, a side surface of the metal plate 140, and a side surface of the frame 150 and the molding member 160. Therefore, the barrier layer 270 is disposed in a part between the molding member 160 and the side surface of the polarizer POL, the side surface of display panel PN, the side surface of the back plate 130, the side surface of the metal plate 140, and the side surface of the frame 150.

That is, the barrier layer 270 may be disposed on the molding member 160 and the side surface of the polarizer POL, the side surface of display panel PN, the side surface of the back plate 130, the side surface of the metal plate 140, and the side surface of the frame 150 in the first non-active area NA1 which is not adjacent to the bending area BA.

In the meantime, the barrier layer 270 may be further disposed in a part or all of the bottom surface of the frame 150. For example, the barrier layer 270 may be disposed on the side surface of the polarizer POL, the side surface of display panel PN, the side surface of the back plate 130, the side surface of the metal plate 140, and the side surface of the frame 150 and further extend to surround a part of the bottom surface of the frame 150. As another example, the barrier layer 270 may extend so as to surround the entire bottom surface of the frame 150.

The barrier layer 270 may include a plurality of particles formed of epoxy or polyurethane, but is not limited thereto. For example, in a process before injecting the molding member 160 after bonding the cover window 120 and the frame 150 on the top and the bottom of the display panel PN, after placing the plurality of particles on the side surface of the polarizer POL, the side surface of display panel PN, the side surface of the back plate 130, the side surface of the metal plate 140, and the side surface of the frame 150, the molding member 160 is filled to form the barrier layer 270, but not limited thereto.

Referring to FIGS. 6 and 7A, the barrier layer 270 is disposed along an inwardly concave shape at the interface between the first adhesive layer AD1 disposed above the display panel PN and the molding member 160. Further, as illustrated in FIG. 7A, the barrier layer 270 is disposed along an inwardly concave shape at the interface between the second adhesive layer AD2 disposed below the display panel PN and the molding member 160.

Referring to FIGS. 6 and 7B, the barrier layer 270 may be disposed along the flat shape between the side surface of the display panel PN and the molding member 160. That is, the barrier layer 270 may be disposed along, not only the flat shape between the side surface of the polarizer POL, the side surface of display panel PN, the side surface of the back plate 130, the side surface of the metal plate 140, and the side surface of the frame 150 and the molding member 160, but also the flat shape between the side surface of the third adhesive layer AD3, the side surface of the fourth adhesive layer AD4, and the side surface of the fifth adhesive layer AD5 and the molding member 160, but not limited thereto.

In the meantime, when the interface between the side surface of the first adhesive layer AD1 and the side surface of the second adhesive layer AD2 disposed on the top and the bottom of the display panel PN and the molding member 160 has a flat shape, the barrier layer 270 may be also disposed along the flat shape.

In the display device 200 according to another exemplary embodiment of the present disclosure, the barrier layer 270 may be disposed at the interface with the molding member 160 so that the stress of the display panel PN due to the contraction and expansion of the molding member 160 may be reduced or minimized. Accordingly, the reliability of the components disposed on the display panel PN may be improved.

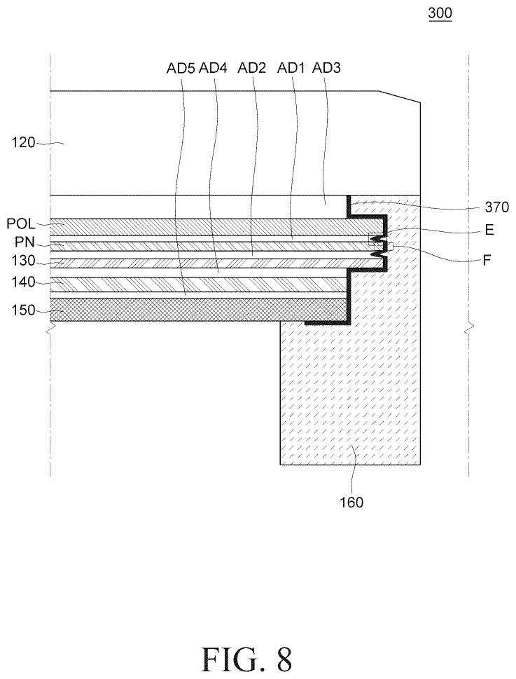

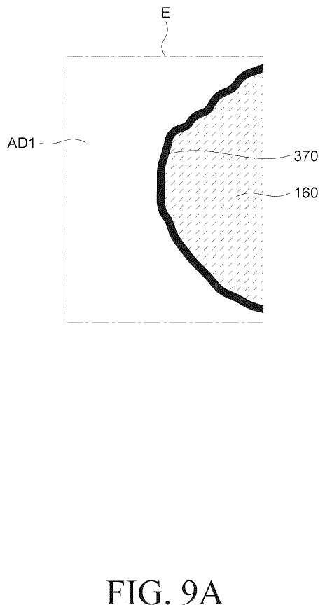

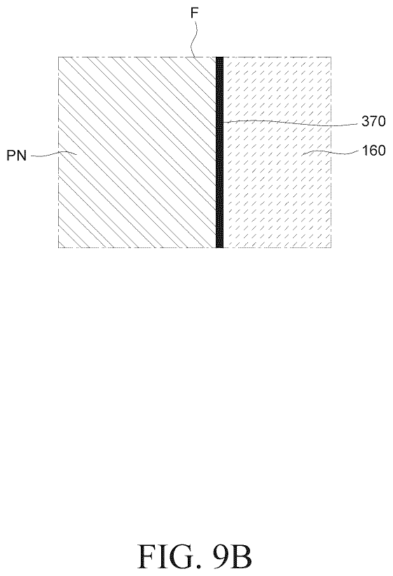

FIG. 8 is a cross-sectional view of a display device according to still another exemplary embodiment of the present disclosure. FIG. 9A is an enlarged cross-sectional view of an area E of FIG. 8 according to an exemplary embodiment of the present disclosure. FIG. 9B is an enlarged cross-sectional view of an area F of FIG. 8 according to an exemplary embodiment of the present disclosure. In FIG. 8, for the convenience of description, among components of a display device 300, a display panel PN, a cover window 120, a polarizer POL, a back plate 130, a metal plate 140, a frame 150, and a molding member 160 are illustrated. The display device 300 of FIG. 8 further includes a barrier layer 370, but the others are the same as the display device 100 of FIGS. 1A to 4 so that a redundant description will be omitted.

Referring to FIG. 8, the barrier layer 370 may be disposed in the first non-active area NA1 which is not adjacent to the bending area BA.

The barrier layer 370 serves as a barrier between side surfaces of the polarizer POL, a side surface of the display panel PN, a side surface of the back plate 130, a side surface of the metal plate 140, and a side surface of the frame 150 and the molding member 160. Therefore, the barrier layer 270 is disposed in a part between the molding member 160 and the side surface of the polarizer POL, the side surface of display panel PN, the side surface of the back plate 130, the side surface of the metal plate 140, and the side surface of the frame 150. The barrier layer 370 may be disposed between the molding member 160 and the side surface of the display panel PN and side surfaces of the plurality of adhesive layers AD1, AD2, AD3, AD4, and AD5. That is, the barrier layer 370 may be disposed on the molding member 160 and the side surface of the polarizer POL, the side surface of display panel PN, the side surface of the back plate 130, the side surface of the metal plate 140, the side surface of the frame 150, and the side surfaces of the plurality of adhesive layers AD1, AD2, AD3, AD4, and AD5 in the first non-active area NA1 which is not adjacent to the bending area BA, but not limited thereto.

In the meantime, the barrier layer 370 may be further disposed in a part or all of the bottom surface of the frame 150. For example, the barrier layer 370 may be disposed on the side surface of the polarizer POL, the side surface of display panel PN, the side surface of the back plate 130, the side surface of the metal plate 140, and the side surface of the frame 150 and further extend to surround a part of the bottom surface of the frame 150. As another example, the barrier layer 370 may extend so as to surround the entire bottom surface of the frame 150, but not limited thereto.

The barrier layer 370 may be formed as a single layer formed of epoxy or polyurethane, but is not limited thereto. For example, in a process before injecting the molding member 160 after bonding the cover window 120 and the frame 150 on the top and the bottom of the display panel PN, after filling and curing a material for forming a liquid state barrier layer 370 on the side surface of the polarizer POL, the side surface of display panel PN, the side surface of the back plate 130, the side surface of the metal plate 140, and the side surface of the frame 150, the molding member 160 is filled to form the barrier layer 370 at the interface with the molding member 160.

Referring to FIGS. 8 and 9A, the barrier layer 370 may be disposed along an inwardly concave shape at the interface between the first adhesive layer AD1 disposed above the display panel PN and the molding member 160. Further, as illustrated in 9A, the barrier layer 370 may be disposed along an inwardly concave shape at the interface between the second adhesive layer AD2 disposed below the display panel PN and the molding member 160.

Referring to FIGS. 8 and 9B, the barrier layer 370 may be disposed along the flat shape between the side surface of the display panel PN and the molding member 160. That is, the barrier layer 370 may be disposed along, not only the flat shape between the side surface of the polarizer POL, the side surface of display panel PN, the side surface of the back plate 130, the side surface of the metal plate 140, and the side surface of the frame 150 and the molding member 160, but also the flat shape between the side surface of the third adhesive layer AD3, the side surface of the fourth adhesive layer AD4, and the side surface of the fifth adhesive layer AD5 and the molding member 160. As shown in FIG. 8, in an area of the first non-active area adjacent to the bending area, the side surfaces of the plurality of adhesive layers AD3, AD4 and AD5 have a flat shape at the interface with the molding member and in other area of the first non-active area, the side surfaces of the plurality of adhesive layers AD1 and AD2 have an inwardly concave shape at a part of the interface with the molding member. Accordingly, the stress due to the contraction and expansion of the molding member 160 is relieved to suppress the crack generated in the display panel PN, thereby reducing or minimizing the defect the display device 100.

In the meantime, even when the interface between the side surface of the first adhesive layer AD1 and the side surface of the second adhesive layer AD2 disposed on the top and the bottom of the display panel PN and the molding member 160 has a flat shape, the barrier layer 370 is also disposed along the flat shape.

In the display device 300 according to another exemplary embodiment of the present disclosure, the barrier layer 370 may be disposed at the interface with the molding member 160 so that the stress of the display panel PN due to the contraction and expansion of the molding member 160 may be reduced or minimized. As a result, the crack of the display panel PN may be suppressed to reduce or minimize the defect of the display device 300.

The exemplary embodiments of the present disclosure can also be described as follows:

According to an aspect of the present disclosure, a display device includes a cover window; a display panel below the cover window, and including an active area, a first non-active area surrounding the active area, a bending area extending from one side of the first non-active area to be bent, and a second non-active area extending from one side of the bending area; a frame below the display panel; a plurality of adhesive layers between the display panel and the cover window and between the display panel and the frame; and a molding member below the cover window so as to cover a side surface of the display panel, side surfaces of the plurality of adhesive layers, a side surface of the frame, and a part of a bottom surface of the frame. A side surface of some of the plurality of adhesive layers has an inwardly concave shape in a part of an interface with the molding member.

A side surface of some of the plurality of adhesive layers may have an irregular shape or an embossing shape.

The display device may further include a polarizer between the cover window and the display panel; a back plate between the display panel and the frame; and a metal plate between the back plate and the frame. The molding member may be disposed so as to surround the side surface of the polarizer, the side surface of the back plate, and the side surface of the metal plate.

The plurality of adhesive layers may include a first adhesive layer between the polarizer and the display panel; and a second adhesive layer between the display panel and the back plate. A side surface of the first adhesive layer and a side surface of the second adhesive layer may have have an inwardly concave shape at the interface with the molding member.

The plurality of adhesive layers may further include a third adhesive layer between the cover window and the polarizer; a fourth adhesive layer between the back plate and the metal plate; and a fifth adhesive layer between the metal plate and the frame. A side surface of the third adhesive layer, a side surface of the fifth adhesive layer, and a side surface of the fifth adhesive layer may have a flat shape at the interface with the molding member.

In the first non-active area adjacent to the bending area, the side surfaces of the plurality of adhesive layers may have a flat shape at the interface with the molding member and in the other first non-active area, the side surfaces of the plurality of adhesive layers may have an inwardly concave shape at a part of the interface with the molding member.

The display device may further include a barrier layer disposed in a part between the molding member and the side surface of the polarizer, the side surface of the display panel, the side surface of the back plate, the side surface of the metal plate, and the side surface of the frame.

The barrier layer may be disposed in the first non-active area which is not adjacent to the bending area.

The barrier layer may include epoxy or polyurethane.

The barrier layer may be formed as a single layer formed of epoxy or polyurethane.

The barrier layer may include a plurality of particles formed of epoxy or polyurethane.

The barrier layer may be further disposed in a part or all of the bottom surface of the frame.

According to another aspect of the present disclosure, a display device include a cover window; a display panel below the cover window and including an active area, a first non-active area surrounding the active area, and a bending area extending from one side of the first non-active area to be bent; a molding member below the cover window so as to cover a side surface of the display panel; and an adhesive layer on the top and the bottom of the display panel so that a side surface of the adhesive layer is covered by the molding member. An interface of the molding member and the adhesive layer has a shape protruding toward the adhesive layer.

The interface of the molding member and the adhesive layer may have an irregular shape or an embossing shape.

The display device may further comprises a polarizer between the cover window and the display panel; a back plate between the display panel and the frame; and a metal plate between the back plate and the frame, wherein the molding member is disposed to surround a side surface of the polarizer, a side surface of the back plate, and a side surface of the metal plate.

The display device may further comprising other adhesive layers between the cover window and the polarizer, between the back plate and the metal plate, and between the metal plate and the frame.

The interface of the molding member and the other adhesive layer in the non-active area adjacent to the bending area may have a flat shape.

The display device may further include a barrier layer between the molding member and a side surface of the display panel and a side surface of the adhesive layer.

The barrier layer may include epoxy or polyurethane.

The barrier layer may be formed as a single layer formed of epoxy or polyurethane.

The barrier layer may include a plurality of particles formed of epoxy or polyurethane.

The barrier layer may be disposed in the non-active area which is not adjacent to the bending area.

According to another aspect of the present disclosure, provided is a manufacture method of a display device, comprising: forming a display panel including an active area, a non-active area adjacent to the active area, and a bending area extending from one side of the non-active area; forming a cover window over the display panel; forming a frame below the display panel; forming a plurality of adhesive layers between the display panel and the cover window and between the display panel and the frame; and forming a molding member below the cover window so as to cover a side surface of the display panel, side surfaces of the plurality of adhesive layers, a side surface of the frame, and a part of a bottom surface of the frame, wherein a side surface of some of the plurality of adhesive layers has an inwardly concave shape in a part of an interface with the molding member.

According to another aspect of the present disclosure, provided is a manufacture method of a display device, comprising: forming a display panel including an active area, a non-active area adjacent to the active area, and a bending area extending from one side of the non-active area; forming a cover window over the display panel; forming a molding member below the cover window so as to cover a side surface of the display pane; forming an adhesive layer on the top and the bottom of the display panel so that a side surface of the adhesive layer is covered by the molding member, wherein an interface of the molding member and the adhesive layer has a shape protruding toward the adhesive layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a cover window;
a display panel below the cover window, the display panel including an active area, a first non-active area surrounding the active area, a bending area extending from one side of the first non-active area to be bent, and a second non-active area extending from one side of the bending area;
a frame below the display panel;
a plurality of adhesive layers between the display panel and the cover window and between the display panel and the frame; and
a molding member below the cover window, the molding member covering a side surface of the display panel, side surfaces of the plurality of adhesive layers, a side surface of the frame, and a part of a bottom surface of the frame,
wherein a side surface of some of the plurality of adhesive layers has an inwardly concave shape in a part of an interface with the molding member.

2. The display device according to claim 1, wherein a side surface of some of the plurality of adhesive layers has an irregular shape or an embossing shape.

3. The display device according to claim 1, further comprising:
a polarizer between the cover window and the display panel;
a back plate between the display panel and the frame; and
a metal plate between the back plate and the frame,
wherein the molding member surrounds the side surface of the polarizer, the side surface of the back plate, and the side surface of the metal plate.

4. The display device according to claim 3, wherein the plurality of adhesive layers include:
a first adhesive layer between the polarizer and the display panel; and
a second adhesive layer between the display panel and the back plate, and
wherein a side surface of the first adhesive layer and a side surface of the second adhesive layer have an inwardly concave shape at the interface with the molding member.

5. The display device according to claim 4, wherein the plurality of adhesive layers further include:
a third adhesive layer between the cover window and the polarizer;
a fourth adhesive layer between the back plate and the metal plate; and
a fifth adhesive layer between the metal plate and the frame, and
wherein a side surface of the third adhesive layer, a side surface of the fourth adhesive layer, and a side surface of the fifth adhesive layer have a flat shape at the interface with the molding member.

6. The display device according to claim 3, wherein in an area of the first non-active area adjacent to the bending area, the side surfaces of the plurality of adhesive layers have a flat shape at the interface with the molding member and in other area of the first non-active area, the side surfaces of the plurality of adhesive layers have an inwardly concave shape at a part of the interface with the molding member.

7. The display device according to claim 3, further comprising:
a barrier layer in a part between the molding member and the side surface of the polarizer, the side surface of the display panel, the side surface of the back plate, the side surface of the metal plate, and the side surface of the frame.

8. The display device according to claim 7, wherein the barrier layer is in an area of the first non-active area that is not adjacent to the bending area.

9. The display device according to claim 7, wherein the barrier layer includes epoxy or polyurethane.

10. The display device according to claim 9, wherein the barrier layer is a single layer including epoxy or polyurethane.

11. The display device according to claim 9, wherein the barrier layer includes a plurality of particles of epoxy or polyurethane.

12. The display device according to claim 7, wherein the barrier layer is further disposed in a part or all of the bottom surface of the frame.

13. A display device, comprising:
a cover window;
a display panel below the cover window, the display panel including an active area, a first non-active area surrounding the active area, and a bending area extending from one side of the first non-active area to be bent;
a molding member below the cover window, the molding member covering a side surface of the display panel; and
an adhesive layer on a top and a bottom of the display panel such that a side surface of the adhesive layer is covered by the molding member,
wherein an interface of the molding member and the adhesive layer has a shape protruding toward the adhesive layer.

14. The display device according to claim 13, wherein the interface of the molding member and the adhesive layer has an irregular shape or an embossing shape.

15. The display device according to claim 13, further comprising:
a polarizer between the cover window and the display panel;
a back plate between the display panel and a frame; and
a metal plate between the back plate and the frame,
wherein the molding member surrounds a side surface of the polarizer, a side surface of the back plate, and a side surface of the metal plate.

16. The display device according to claim 15, further comprising:
other adhesive layers between the cover window and the polarizer, between the back plate and the metal plate, and between the metal plate and the frame.

17. The display device according to claim 16, wherein the interface of the molding member and the other adhesive layers in an area of the first non-active area adjacent to the bending area has a flat shape.

18. The display device according to claim 13, further comprising:
a barrier layer between the molding member and a side surface of the display panel and a side surface of the adhesive layer.

19. The display device according to claim 18, wherein the barrier layer includes epoxy or polyurethane.

20. The display device according to claim 19, wherein the barrier layer is a single layer including epoxy or polyurethane.

21. The display device according to claim 19, wherein the barrier layer includes a plurality of particles of epoxy or polyurethane.

22. The display device according to claim 18, wherein the barrier layer is disposed in an area of the first non-active area which is not adjacent to the bending area.

23. A manufacture method of a display device, comprising:
forming a display panel including an active area, a non-active area adjacent to the active area, and a bending area extending from one side of the non-active area;
forming a cover window over the display panel;
forming a frame below the display panel;
forming a plurality of adhesive layers between the display panel and the cover window and between the display panel and the frame; and
forming a molding member below the cover window, the molding member covering a side surface of the display panel, side surfaces of the plurality of adhesive layers, a side surface of the frame, and a part of a bottom surface of the frame,
wherein a side surface of some of the plurality of adhesive layers has an inwardly concave shape in a part of an interface with the molding member.

24. A manufacture method of a display device, comprising:
forming a display panel including an active area, a non-active area adjacent to the active area, and a bending area extending from one side of the non-active area;
forming a cover window over the display panel;
forming a molding member below the cover window, the molding member covering a side surface of the display panel;
forming an adhesive layer on a top and a bottom of the display panel such that a side surface of the adhesive layer is covered by the molding member,
wherein an interface of the molding member and the adhesive layer has a shape protruding toward the adhesive layer.
